(19) United States
(12) Patent Application Publication
(10) Pub. No.: US 2015/0249427 A1
(43) Pub. Date: Sep. 3, 2015

(54) SOLAR CELL AND METHOD FOR CALCULATING RESISTANCE OF SOLAR CELL

(71) Applicant: Panasonic Intellectual Property Management Co., Ltd., Osaka (JP)

(72) Inventor: Keiichiro MASUKO, Osaka (JP)

(21) Appl. No.: 14/713,547

(22) Filed: May 15, 2015

Related U.S. Application Data
(63) Continuation of application No. PCT/JP2013/006773, filed on Nov. 19, 2013.

(30) Foreign Application Priority Data
Nov. 19, 2012 (JP) 2012-253255

(51) Int. Cl. H02S 50/10; H01L 31/0376

(52) U.S. Cl. CPC H02S 50/10; H01L 31/0376

(57) ABSTRACT

A solar cell has a photoelectric conversion unit in which an n-type region including an n-type amorphous semiconductor layer and a p-type region including a p-type amorphous semiconductor layer are disposed in a planar manner, light such as solar light is received, and photoproduction carriers including holes and electrons are generated. Electrodes through which the photoelectrically converted electric power is taken out are also provided, and a resistance measurement unit is provided in an outer periphery of an electrode region in which the electrodes are disposed. The resistance measurement unit has two measurement electrodes extending from the n-type region and one measurement electrode extending from the p-type region, and the measurement electrodes are disposed with a predetermined inter-electrode space therebetween.

### CROSS-REFERENCE TO RELATED APPLICATIONS

The present application is a continuation under 35 U.S.C. §120 of PCT/JP2013/006773, filed Nov. 19, 2013, which is incorporated herein by reference and which claimed priority under 35 U.S.C. §119 to Japanese Patent Application No. 2012-253255 filed on Nov. 19, 2012, the entire content of which is also incorporated herein by reference.

### BACKGROUND

1. Technical Field

The present invention relates to a solar cell and a method of calculating a resistance of a solar cell.

2. Related Art

In order to stably produce a solar cell in which an amorphous semiconductor layer is formed over a semiconductor substrate, it is effective to calculate a resistance between the semiconductor substrate and an electrode formed over the amorphous semiconductor layer, and to feed back the resistance to the condition of production.

Patent Document 1 discloses a method of calculating a contact resistance between a diffusion layer of a photovoltaic element and an electrode. In Patent Document 1, samples are prepared by applying a silver paste by screen printing in direct contact with the diffusion layer on a primary surface side of the photovoltaic element, to form a first electrode and a second electrode, such that inter-electrode distances D between the first electrode and the second electrode are varied from 1 mm to 5 mm, and the contact resistances thereof are measured. In this method, a model is employed based on a TLM (Transmission Line Model), and in which a contact resistance is connected to each of the ends of the resistance of the diffusion layer. The contact resistance is then calculated based on the fact that the resistance of the diffusion layer changes proportional to the inter-electrode distance D when the inter-electrode distance D is changed.

### RELATED ART REFERENCE

### Patent Document

### [Patent Document 1] JP 2008-205398 A

An advantage of the present invention is that a resistance between a semiconductor substrate and an electrode formed over an amorphous semiconductor layer is calculated using a solar cell which will be manufactured as a commercial product.

### SUMMARY

According to one aspect of the present invention, there is provided a solar cell comprising: a photoelectric conversion unit in which an amorphous semiconductor layer of a first conductivity type and an amorphous semiconductor layer of a second conductivity type are disposed over one surface of a semiconductor substrate of the first conductivity type; a first electrode disposed in a first electrode region which is defined in advance, of the amorphous semiconductor layer of the first conductivity type; a second electrode disposed in a second electrode region which is defined in advance, of the amorphous semiconductor layer of the second conductivity type; and at least two first measurement electrodes provided with a predetermined space therebetween over the amorphous semiconductor layer of the first conductivity type.

According to another aspect of the present invention, there is provided a method of calculating a resistance of a solar cell in which an amorphous semiconductor layer of a first conductivity type and an amorphous semiconductor layer of a second conductivity type are disposed over one surface of a semiconductor substrate of the first conductivity type, a first electrode is disposed over the amorphous semiconductor layer of the first conductivity type, and a second electrode is disposed over the amorphous semiconductor layer of the second conductivity type, and in which a resistance between the semiconductor substrate and at least one of the first electrode and the second electrode is measured, the method comprising: measuring a voltage-current characteristic between at least two first measurement electrodes provided with a predetermined space therebetween over the amorphous semiconductor layer of the first conductivity type, to determine an inter-measurement electrode resistance, and subtracting, from the inter-measurement electrode resistance, an inter-measurement electrode resistance of the semiconductor substrate which is determined in advance, to calculate a first resistance between the semiconductor substrate and the first measurement electrode.

### Advantageous Effect

According to various aspects of the present invention, a resistance including a contact resistance between an amorphous semiconductor layer and an electrode can be calculated in a solar cell in which the amorphous semiconductor layer is formed over a semiconductor substrate.

### BRIEF DESCRIPTION OF THE DRAWINGS

FIG. 1 is a plan view of a back surface side of a solar cell according to a preferred embodiment of the present invention.

FIG. 2 is a cross sectional diagram of a solar cell according to a preferred embodiment of the present invention.

FIG. 3 is a cross sectional diagram along a line A-A of FIG. 1.

FIG. 4 is a diagram for explaining calculation of resistance in a solar cell according to a preferred embodiment of the present invention.

FIG. 5 is a diagram showing another example placement of measurement electrodes.

FIG. 6 is a diagram showing yet another example placement of measurement electrodes.

FIG. 7 is a diagram showing another example placement of measurement electrodes.

FIG. 8 is a diagram showing yet another example placement of measurement electrodes.

### DETAILED DESCRIPTION

A preferred embodiment of the present invention will now be described in detail with reference to the drawings. The thicknesses or the like described below are merely exemplary for the purpose of explaining the invention, and may be suitably changed according to the specification of the solar cell. In addition, in the following description, the same or corresponding elements in all drawings are assigned the same reference numerals, and will not be repeatedly described.

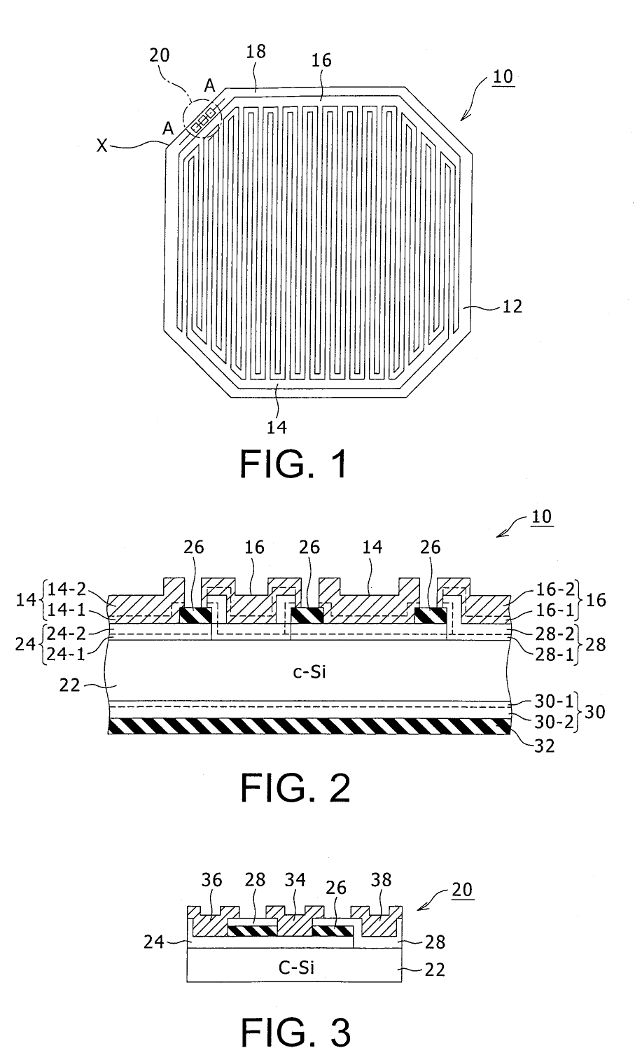

FIG. 1 is a plan view of a back surface side of a back contact type solar cell 10. In the back contact type solar cell 10, a pn junction in which photovoltaic conversion takes place is formed over aback surface which is on a side opposite to a light receiving surface, and the electrodes are provided only on the back surface side. As described, because the electrode is not disposed over the light receiving surface, the light receiving area can be widened, and photoelectric conversion efficiency per unit area can be improved. In FIG. 1, the side of the front surface of the page is the light receiving surface side and the side of the back surface of the page is the back surface side. In the following, the back contact type solar cell 10 will simply be referred to as a solar cell 10, unless otherwise specified.

The solar cell 10 has a photoelectric conversion unit 12 in which an n-type amorphous semiconductor layer and a p-type amorphous semiconductor layer are disposed in a planar manner over an n-type semiconductor substrate, light such as solar light is received, and photoproduction carriers such as holes and electrons are produced, and electrodes 14 and 16 are also provided through which the photoelectrically converted electric power is taken out. As will be described below, the electrodes 14 and 16 have a layered structure of transparent conductive film layers 14-1 and 16-1 and Cu plating layers 14-2 and 16-2, respectively. In addition, on an outer periphery 18 of an electrode region in which the electrodes 14 and 16 are disposed, a resistance measurement unit 20 is provided including a plurality of measurement electrodes for measuring a resistance including a contact resistance between the amorphous semiconductor layer and the electrode.

FIG. 2 is a cross sectional diagram showing a structure of the back contact type solar cell 10. The cross sectional diagram is a cross sectional diagram at the electrode region in which the electrodes 14 and 16 are disposed. In FIG. 2, the upper side of the page is the back surface side of the solar cell 10, and the lower side is the light receiving surface side.

In FIG. 2, a substrate 22 is formed with a crystalline semiconductor material. The substrate 22 may be a crystalline semiconductor substrate of an n conductivity type or a p conductivity type. As the substrate 22, a monocrystalline silicon substrate, a polycrystalline silicon substrate, a gallium arsenide (GaAs) substrate, an indium phosphide (InP) substrate, or the like may be employed. The substrate 22 absorbs incident light to generate carrier pairs of electrons and holes through photovoltaic reaction. Here, an n-type silicon monocrystal is used as the substrate 22. In FIG. 2, the substrate 22 is shown as c-Si.

An n-type region 24 has a layered structure of an i-type amorphous semiconductor layer 24-1 and an n-type amorphous semiconductor layer 24-2. In the following, the i-type amorphous semiconductor layer is also referred to as an i layer, and the n-type amorphous semiconductor layer is also referred to as an n layer. Similarly, a p-type amorphous semiconductor layer is also referred to as a p layer.

The i layer 24-1 is formed over the entire surface of the substrate 22. The i layer 24-1 is, for example, an amorphous semiconductor layer including hydrogen. An example thickness of the i layer may be about 1 nm to about 25 nm, and a preferable thickness is about 5 nm to about 10 nm. The n-layer 24-2 is formed over the entire surface of the i layer 24-1. The n layer 24-2 includes a donor which is an element of an n conductivity type, in an amorphous semiconductor layer including hydrogen. An example thickness of the n layer is about 5 nm to about 20 nm, and a preferable thickness is about 10 nm to about 15 nm.

A SiN_{X} layer 26 is a silicon nitride film layer used for separating the n-type region and the p-type region, or the like. The SiN_{X} layer 26 is formed in a region over the n layer 24-2, corresponding to the n-type region 24. A representative example of silicon nitride is Si₃N₄, but depending on the film formation condition, the composition Si₃N₄ is not necessarily obtained, and in general, a composition of SiN_{X} is obtained. An example thickness of the SiN_{X} layer 26 is about 10 nm to about 500 nm, and a preferable thickness is about 50 nm to about 100 nm.

A p-type region 28 has a layered structure of an i layer 28-1 and a p layer 28-2. The i layer 28-1 is formed over an exposed substrate 22 using the SiN_{X} layer 26 as a mask, and exposing the substrate 22 by removing the i layer 24-1 and the n layer 24-2 in regions other than the n-type region. The i layer 28-1 may be am amorphous semiconductor layer including hydrogen, similar to the i layer 24-1. Also, similar to the i layer 24-1, the thickness of the i layer 28-1 may be about 1 nm to about 25 nm, and is preferably about 5 nm to about 10 nm. The p layer 28-2 is formed over the i layer 28-1. The p layer 28-2 includes an acceptor which is an element of a p conductivity type in an amorphous semiconductor layer including hydrogen. An example thickness of the p layer 28-2 is about 5 nm to about 20 nm, and a preferable thickness is about 10 nm to about 15 nm.

The electrodes 14 and 16 have layered structures of the transparent conductive film layers 14-1 and 16-1 and the Cu plating layers 14-2 and 16-2, respectively. The electrode 14 is an electrode for the n-type extending from the n-type region 24, and formed by layering the transparent conductive film layer 14-1 and the Cu plating layer 14-2 over the n layer 24-2. The electrode 16 is an electrode for the p-type extending from the p-type region 28, and is formed by layering the transparent conductive film layer 16-1 and the Cu plating layer 16-2 over the p layer 28-2.

Each of the transparent conductive film layers 14-1 and 16-1 is formed, for example, including a metal oxide having a polycrystalline structure such as indium oxide (In₂O₃), zinc oxide (ZnO), tin oxide (SnO₂), titanium oxide (TiO₂), or the like. An example thickness for the transparent conductive film layers 14-1 and 16-1 is about 70 nm to about 100 nm.

The Cu plating layers 14-2 and 16-2 are formed by electroplating. An example thickness for the Cu plating layers 14-2 and 16-2 is about 10 μm to about 20 μm. During the formation of the Cu plating layers 14-2 and 16-2, an underlying electrode layer may be used. In addition, a Sn plating layer may be formed over the Cu plating layers 14-2 and 16-2.

A passivation layer 30 on the light receiving surface side is a layer that protects a surface which is alight receiving surface of the substrate 22 in which the photovoltaic reaction takes place, and has a layered structure of an i layer 30-1 and an n layer 30-2. As described above, on the back surface side of the substrate 22, the i layer 24-1 and the n layer 24-2 for the n-type region 24 are formed, and during this process, the i layer 30-1 and the n layer 30-2 may be formed on the light receiving surface side of the substrate 22, to form the passivation layer 30.

A reflection prevention layer 32 is an insulating film layer having a function to inhibit reflection on the light receiving surface, and a SiN_{X} layer is used. During the formation of the SiN_{X} layer 26 executed after the formation of the n-type region 24 on the back surface side of the substrate 22, the SiN_{X} layer may also be formed on the light receiving surface side of the substrate 22, to form the reflection prevention layer 32.

FIG. 3 is a cross sectional diagram of the resistance measurement unit 20. The resistance measurement unit 20 is a group of a plurality of measurement electrodes provided over an outer periphery 18 on an outer side of the electrode region in which the electrodes 14 and 16 are disposed in the solar cell 10, for measuring a resistance between the substrate 22 and the electrode over the n-type region or between the substrate 22 and the electrode over the p-type region. In the following, a resistance between the substrate 22 and the electrode over the n-type region 24 will be described as an n-type resistance, and a resistance between the substrate 22 and the electrode over the p-type region 28 will be described as a p-type resistance. In FIG. 3, three measurement electrodes 34, 36, and 38 are shown, but alternatively, more measurement electrodes may be provided. In FIG. 3, the layered structures for the n-type region 24, the p-type region 28, and the electrodes 14 and 16 are not shown.

On the outer periphery 18, the electrodes 14 and 16 are not disposed. However, by adjusting the position of the mask during formation of the layers in the formation steps of the electrodes 14 and 16, it is possible to form an arbitrary electrode structure also in the outer periphery 18. Thus, an n-type region 24 is formed in the outer periphery 18 with the same condition as the electrode region, and at least two measurement electrodes are provided with a predetermined electrode space therebetween in the formed n-type region 24. A current-voltage characteristic (I-V characteristic) between the measurement electrodes is measured, and the n-type resistance between the measurement electrode and the substrate 22 is calculated based on the I-V characteristic. Similarly, a p-type region 28 is formed in the outer periphery 18 with the same condition as the electrode region, and at least one measurement electrode is provided in the formed p-type region 28. An I-V characteristic between the measurement electrode over the n-type region 24 and the measurement electrode over the p-type region 28 is measured, and a first resistance between the measurement electrode over the n-type region 24 and the measurement electrode over the p-type region 28 is calculated. Based on the calculated n-type resistance and the calculated first resistance, the p-type resistance between the substrate 22 and the measurement electrode over the p-type region 28 is calculated. Here, the n-type resistance and the p-type resistance include the resistances of the interfaces between layers between the substrate 22 and the measurement electrode, the i layer 24-1 or the i layer 28-1, and the n layer 24-2 or the p layer 28-2. In this manner, the resistance measurement unit 20 can separately and independently measure the n-type resistance between the substrate 22 and the measurement electrode over the n-type region 24 and the p-type resistance between the substrate 22 and the measurement electrode over the p-type region 28.

In FIG. 3, planar dimensions of the three measurement electrodes 34, 36, and 38 are set to be equal to each other, and inter-electrode spaces among the three measurement electrodes 34, 36, and 38 are also set to be equal to each other. The measurement electrodes 34 and 36 extend from the n-type region 24, and the measurement electrode 38 extends from the p-type region 28. The three measurement electrodes 34, 36, and 38 are arranged in one line along a side X on an outer circumference of the solar cell 10 in the outer periphery 18. The planar dimensions of and the inter-electrode spaces between the three measurement electrodes 34, 36, and 38 are set sufficiently small compared to the dimension of the outer periphery 18 in a width direction (direction perpendicular to the side X). For example, the planar dimension and the inter-electrode space may be preferably set to less than or equal to 1/10th of the dimension of the outer periphery 18 in the width direction. An example dimension of the outer periphery 18 in the width direction is about 1 mm to about 3 mm. An example planar dimension of the measurement electrodes 34, 36, and 38 in this case may be a square having a side of about 100 μm to about 500 μm. An example inter-electrode space between the measurement electrode 34 and the measurement electrode 36 and an example inter-electrode space between the measurement electrode 36 and the measurement electrode 38 is about 50 μm to about 200 μm.

Using this structure, the I-V characteristic between the measurement electrodes 34 and 36 extending from the n-type region 24 is determined, and the n-type resistance between the substrate 22 and the measurement electrodes 34 and 36 over the n-type region 24 can be calculated based on the I-V characteristic. Then, the I-V characteristic between the measurement electrode 34 extending from the n-type region 24 and the measurement electrode 38 extending from the p-type region 28 is determined, and a first resistance between the measurement electrode 34 and the measurement electrode 38 can be calculated based on the I-V characteristic. Using the calculated n-type resistance and the calculated first resistance, it is possible to calculate the p-type resistance between the substrate 22 and the measurement electrode 38 over the p-type region 28.

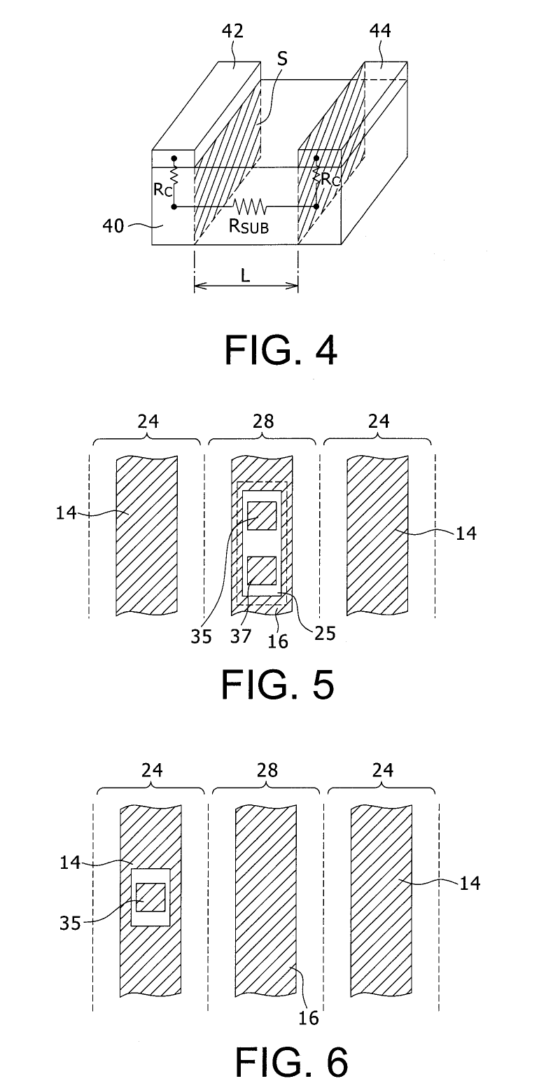

A measurement principle of a resistance R_{C} will be explained using a model shown in FIG. 4. In the model of FIG. 4, two measurement electrodes 42 and 44 are provided over a semiconductor layer 40 with an inter-electrode space L, a current I is applied between the measurement electrodes 42 and 44, a voltage V between the measurement electrodes 42 and 44 is measured, an inter-measurement electrode resistance R is determined, and a resistance R_{C} between the semiconductor layer 40 and the measurement electrodes 42 and 44 is determined based on the inter-measurement electrode resistance R. The inter-measurement electrode resistance R may alternatively be determined by first applying the voltage V between the measurement electrodes 42 and 44, and measuring the current I flowing between the measurement electrodes 42 and 44.

When the current I is applied between the measurement electrodes 42 and 44 and the voltage between the measurement electrodes 42 and 44 is V, the inter-measurement electrode resistance R can be determined by R=V/I. As shown in FIG. 4, when the inter-measurement electrode distance is L and an area of the semiconductor layer 40 facing with the distance L is S, an inter-measurement electrode resistance R_{SUB} of the semiconductor layer 40 can be determined by R_{SUB}=ρ×(L/S) where a specific resistance of the semiconductor layer 40 is ρ. If the resistance between the semiconductor layer 40 and the measurement electrode 42 and the resistance between the semiconductor layer 40 and the measurement electrode 44 are assumed to be the same and are R_{C}, R=I/V=R_{SUB}+2R_{C}. Based on this equation, the resistance R_{C} between the semiconductor layer 40 and the measurement electrodes 42 and 44 can be calculated as R_{C}={(R−R_{SUB})/2}.

Referring again to FIG. 3, by applying a current I_{34·36} between the measurement electrodes 34 and 36 and measuring the voltage V_{34·36} between the measurement electrodes 34 and 36, it is possible to calculate the resistance R_{Cn} between the n-type region 24 and the measurement electrodes 34 and 36 as R_{Cn}={(R_{34·36}−R_{SUBn})/2} based on the above-described principle. Here, R_{34·36}=V_{34·36}/I_{34·36}. R_{SUBn} is an inter-electrode resistance between the substrate 22 and the n-type region 24, and, in practice, may be assumed to be an inter-electrode resistance R_{SUB22} of the substrate 22. The R_{Cn} thus determined can be used as the n-type resistance between the substrate 22 and the electrode 14 over the n-type region 24 in the electrode region of the solar cell 10. The n-type resistance includes the resistances of the interfaces of the layers between the substrate 22 and the electrode 14, the i layer 24-1, and the n layer 24-2.

Next, by applying a current I_{34·38} between the measurement electrodes 34 and 38 and measuring a voltage V_{V34·38} between the measurement electrodes 34 and 38, it is possible to obtain a current-voltage characteristic between the measurement electrodes 34 and 38. The current-voltage characteristic corresponds to the current-voltage characteristic between the electrode for the n-type and the electrode for the p-type of the solar cell 10, and the following equation can be used with a current of I and a voltage of V.

$$I = {I}_{0} [ exp ( \frac{e ( V + {R}_{s} I )}{{nk}_{B} T} ) - 1 ] + \frac{V + {R}_{s} I}{{R}_{sh}} \qquad [ Equation 1 ]$$

Here, k_{B} represents the Boltzmann constant, T represents a temperature, and R_{S} and R_{Sh} represent a series resistance and a parallel resistance when a model is employed in which the solar cell 10 is represented as small photoelectric conversion units connected in series.

In the above-described I-V characteristic, with I=I_{34·38} and V=V_{34·38}, a non-linear inter-electrode resistance R_{S}=R_{34·38} is determined. Here, when the inter-electrode resistance between the substrate 22 and the p-type region 28 is R_{SUBp} and the resistance between the p-type region 28 and the measurement electrode 38 is R_{Cp}, R_{34·38}=R_{SUBp}+R_{Cn}+R_{Cp}. Therefore, the resistance R_{Cp} is calculated as R_{Cp}={(R_{34·38}−R_{SUBp})−R_{Cn}}. R_{SUBp} is an inter-electrode resistance between the substrate 22 and the p-type region 28, and, in practice, may be assumed to be the inter-electrode resistance R_{SUB22} of the substrate 22. The resistance R_{Cp} determined in this manner can be used as the p-type resistance between the substrate 22 and the electrode 16 over the p-type region 28 in the electrode region of the solar cell 10. Here, the p-type resistance includes the resistances of the interfaces of the layers between the substrate 22 and the electrode 16, the i layer 28-1, and the p layer 28-2.

In the above, it is described that the inter-electrode resistance of the semiconductor layer 40 is determined as R_{SUB}=ρ×(L/S). The model of FIG. 4 assumes that L is sufficiently long and S is sufficiently wide, but there may be cases where L is short. In the model of FIG. 4, because L is a length that contributes to the resistance when the current flows, if L is short, R_{SUB} is preferably determined while applying a correction to L. For example, a correction coefficient of a may be employed, and R_{SUB} may be determined using αL/S with the corrected L. The coefficient α may be determined through experiments or the like.

In the present embodiment, the resistance measurement unit 20 is provided in the outer periphery 18 of the solar cell 10, but alternatively, the resistance measurement unit 20 may be provided in the electrode region of the solar cell 10. Structures when the resistance measurement unit 20 is provided in the electrode region will now be described with reference to FIGS. 5-8. FIGS. 5-8 are enlarged diagrams of a portion of the electrode region on the back surface of the solar cell 10.

In FIG. 5, an n-type region 25 is formed in a center portion of the p-type region 28, and two measurement electrodes 35 and 37 are provided with a predetermined electrode space therebetween. In other words, the two measurement electrodes 35 and 37 are surrounded by the electrode 16 with a predetermined space therebetween. With such a configuration, the n-type resistance can be calculated using the two measurement electrodes 35 and 37, and the first resistance can be calculated using the measurement electrodes 35 and 37 and the electrode 16. The p-type resistance is calculated based on the n-type resistance and the first resistance.

In FIG. 5, the n-type region 25 is formed in the center portion of the p-type region 28, but alternatively, an n-type region 25 may be formed in the center portion of the n-type region 24 and two measurement electrodes 35 and 37 may be provided. In other words, the measurement electrodes 35 and 37 are surrounded by the electrode 14 with a predetermined space therebetween. In this case, the n-type resistance can be calculated using the two measurement electrodes 35 and 37. The first resistance can be calculated using the electrode 14 and the electrode 16 adjacent to the electrode 14. The n-type regions 24 and 25 may be simultaneously formed or may be formed at separate times.

In FIG. 6, one measurement electrode 35 is provided in the center portion of the n-type region 24. In other words, the measurement electrode 35 is surrounded by the electrode 14 with a predetermined space therebetween. With such a configuration, the n-type resistance can be calculated using the measurement electrode 35 and the electrode 14, and the first resistance can be calculated using the electrode 14 and the electrode 16 adjacent to the electrode 14. Based on the n-type resistance and the first resistance, the p-type resistance is calculated.

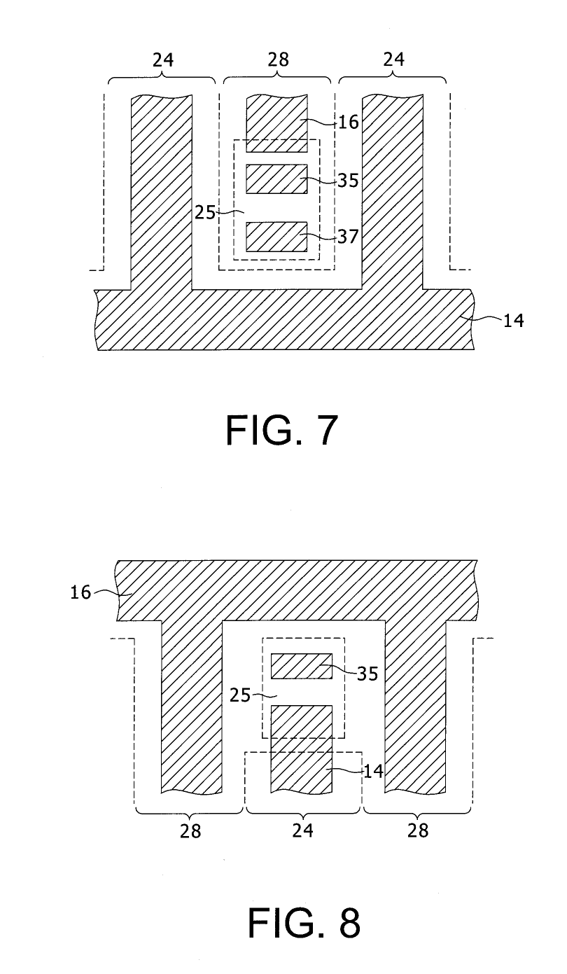

In FIG. 7, the n-type region 25 is formed between a tip of the electrode 16 and the electrode 14, and two measurement electrodes 35 and 37 are provided with a predetermined electrode space. With such a configuration, the n-type resistance can be calculated using the two measurement electrodes 35 and 37, and the first resistance can be calculated using the electrode 16 and the measurement electrodes 35 and 37 or the electrode 14 adjacent to the electrode 16. Based on the n-type resistance and the first resistance, the p-type resistance is calculated.

In FIG. 8, the n-type region 25 is formed between a tip of the electrode 14 and the electrode 16, and one measurement electrode 35 is provided with a predetermined space from the electrode 14. With such a configuration, the n-type resistance can be calculated using the measurement electrode 35 and the electrode 14. Based on the n-type resistance and the first resistance, the p-type resistance is calculated. The n-type regions 24 and 25 may be simultaneously formed or may be formed at separate times.

As described, the location where the resistance measurement unit 20 is provided is not particularly limited. In addition, by providing at least two electrodes over the n-type regions 24 and 25 with a predetermined electrode space, the n-type resistance can be calculated. In the case of the back contact type solar cell 10, the electrode 14 provided over the n-type region 24 and the electrode 16 provided over the p-type region 28 are disposed alternatingly and adjacent to each other with a predetermined space. Therefore, the first resistance can be easily calculated using the electrodes 14 and 16. In other words, by merely providing at least two electrodes over the n-type regions 24 and 25 with a predetermined electrode space, it is possible to easily calculate even the p-type resistance between the substrate 22 and the electrode over the p-type region 28.

In the present embodiment, because the n-type silicon monocrystal is used as the substrate 22, at least two electrodes are provided over the n-type region 24 with a predetermined electrode space. When a p-type crystalline semiconductor substrate is used as the substrate 22, advantages similar to the above can be obtained when at least two electrodes are provided over the p-type region 28 with a predetermined electrode space.

### INDUSTRIAL APPLICABILITY

The present invention can be applied to a solar cell.

### EXPLANATION OF REFERENCE NUMERALS

10 SOLAR CELL; 12 PHOTOELECTRIC CONVERSION UNIT; 14, 16 ELECTRODE; 14-1, 16-1 TRANSPARENT CONDUCTIVE FILM LAYER; 14-2, 16-2 PLATING LAYER; 18 OUTER PERIPHERY; 20 RESISTANCE MEASUREMENT UNIT; 22 SUBSTRATE; 24, 25 n-TYPE REGION; 24-1, 28-1, 30-1 i LAYER (i-TYPE AMORPHOUS SEMICONDUCTOR LAYER); 24-2, 30-2 n LAYER (n-TYPE AMORPHOUS SEMICONDUCTOR LAYER); 26 SiN_{X} LAYER; 28 p-TYPE REGION; 28-2 p LAYER (p-TYPE AMORPHOUS SEMICONDUCTOR LAYER); 30 PASSIVATION LAYER; 32 REFLECTION PREVENTION LAYER; 34, 35, 36, 37, 38, 42, 44 MEASUREMENT ELECTRODE; 40 SEMICONDUCTOR LAYER.

1. A solar cell comprising:
a photoelectric conversion unit in which an amorphous semiconductor layer of a first conductivity type and an amorphous semiconductor layer of a second conductivity type are disposed over one surface of a semiconductor substrate of the first conductivity type;
a first electrode disposed in a first electrode region which is defined in advance, of the amorphous semiconductor layer of the first conductivity type;
a second electrode disposed in a second electrode region which is defined in advance, of the amorphous semiconductor layer of the second conductivity type; and
at least two first measurement electrodes provided with a predetermined space therebetween over the amorphous semiconductor layer of the first conductivity type.

2. The solar cell according to claim 1, further comprising:
at least one second measurement electrode provided with a predetermined space with respect to the first measurement electrode over the amorphous semiconductor layer of the second conductivity type.

3. The solar cell according to claim 1, wherein
the first measurement electrode is disposed in a region other than the first electrode region and the second electrode region over the photoelectric conversion unit.

4. The solar cell according to claim 2, wherein
the first measurement electrode and the second measurement electrode are disposed in a region other than the first electrode region and the second electrode region over the photoelectric conversion unit.

5. The solar cell according to claim 1, wherein
the at least two first measurement electrodes are provided adjacent to each other.

6. The solar cell according to claim 2, wherein
one of the first measurement electrodes and the second measurement electrode are provided adjacent to each other.

7. A solar cell, comprising:
a photoelectric conversion unit in which an amorphous semiconductor layer of a first conductivity type and an amorphous semiconductor layer of a second conductivity type are disposed over one surface of a semiconductor substrate of the first conductivity type;
a first electrode disposed in a first electrode region which is defined in advance, of the amorphous semiconductor layer of the first conductivity type;
a second electrode disposed in a second electrode region which is defined in advance, of the amorphous semiconductor layer of the second conductivity type; and
a third measurement electrode disposed over the amorphous semiconductor layer of the first conductivity type, wherein
the third measurement electrode is disposed with a predetermined space with the first electrode and adjacent to the first electrode.

8. The solar cell according to claim 7, wherein
the third measurement electrode is disposed in a center portion of the first electrode in a manner to be surrounded by the first electrode.

9. A method of calculating a resistance of a solar cell in which an amorphous semiconductor layer of a first conductivity type and an amorphous semiconductor layer of a second conductivity type are disposed over one surface of a semiconductor substrate of the first conductivity type, a first electrode is disposed over the amorphous semiconductor layer of the first conductivity type, and a second electrode is disposed over the amorphous semiconductor layer of the second conductivity type, and in which a resistance between the semiconductor substrate and at least one of the first electrode and the second electrode is measured, the method comprising:
measuring a voltage-current characteristic between at least two first measurement electrodes provided with a predetermined space therebetween over the amorphous semiconductor layer of the first conductivity type, to determine an inter-measurement electrode resistance; and
subtracting, from the inter-measurement electrode resistance, an inter-measurement electrode resistance of the semiconductor substrate which is determined in advance, to calculate a first resistance between the semiconductor substrate and the first measurement electrode.

10. The method of calculating the resistance of the solar cell according to claim 9, further comprising:
measuring a voltage-current characteristic between the first measurement electrode and a second measurement electrode using at least one second measurement electrode provided with a predetermined space with the first measurement electrode over the amorphous semiconductor layer of the second conductivity type, to determine a second inter-measurement electrode resistance; and
subtracting the inter-measurement electrode resistance of the semiconductor substrate and the first resistance from the second inter-measurement electrode resistance, to calculate a second resistance between the semiconductor substrate and the second measurement electrode.

11. The method of calculating the resistance of the solar cell according to claim 9, wherein
the inter-electrode resistance of the semiconductor layer is corrected according to the space between the two first measurement electrodes and the space between the first measurement electrode and the second measurement electrode.

12. The solar cell according to claim 2, wherein
the at least two first measurement electrodes are provided adjacent to each other.

13. The solar cell according to claim 3, wherein
the at least two first measurement electrodes are provided adjacent to each other.

14. The solar cell according to claim 4, wherein
the at least two first measurement electrodes are provided adjacent to each other.

15. The solar cell according to claim 4, wherein
one of the first measurement electrodes and the second measurement electrode are provided adjacent to each other.

16. The method of calculating the resistance of the solar cell according to claim 10, wherein
the inter-electrode resistance of the semiconductor layer is corrected according to the space between the two first measurement electrodes and the space between the first measurement electrode and the second measurement electrode.
